(19) United States
(12) Patent Application Publication
(10) Pub. No.: US 2026/0013199 A1
(43) Pub. Date: Jan. 8, 2026

(54) HEAT DISSIPATION FOR DEVICES

(71) Applicant: Taiwan Semiconductor Manufacturing Company, Ltd., Hsinchu (TW)

(72) Inventor: Tzu-Ging Lin, Kaohsiung City (TW)

(21) Appl. No.: 18/765,025

(22) Filed: Jul. 5, 2024

(51) Int. Cl. H01L 29/417; H01L 21/8238; H01L 27/092; H01L 29/06; H01L 29/423; H01L 29/775; H01L 29/786

(52) U.S. Cl. CPC H10D 64/254; H10D 84/0186; H10D 84/038; H10D 84/85; H10D 30/43; H10D 30/6735; H10D 30/6757; H10D 62/121

(57) ABSTRACT

A semiconductor device according to the present disclosure includes a p-type transistor and an n-type transistor disposed over a backside dielectric layer. The p-type transistor includes a first p-type epitaxial feature, a second p-type epitaxial feature, a first active region extending between the first p-type epitaxial feature and the second p-type epitaxial feature, and a first gate structure wrapping over the first active region. The n-type transistor includes a first n-type epitaxial feature, a second n-type epitaxial feature, a second active region extending between the first n-type epitaxial feature and the second n-type epitaxial feature, and a second gate structure wrapping over the second active region. The semiconductor device further includes a backside contact extending through the backside dielectric layer to engage bottom surfaces of the first p-type epitaxial feature and the first n-type epitaxial feature.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

The shrinkage in device dimensions presents stress on electrical routing. When only a frontside interconnect structure is present, the limited space may lead to smaller interconnect features, smaller spacing between neighboring metal features, and less-than-ideal heat dissipation. The tight spacing and the high contact resistance may lead to high resistance and capacitance, which may lead to low drive current and slow speed.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 schematically illustrates a diagram explaining how flow of holes leads to cooling of a source and heating of a drain of a p-type transistor.

FIG. 2 schematically illustrates a diagram explaining how flow of electrons leads to cooling of a source and heating of a drain of an n-type transistor.

FIG. 3 illustrates example devices where a drain of a p-type device is coupled to a drain an n-type device.

FIG. 4 schematically illustrates enhanced heating of a common drain node where a drain of a p-type device is coupled to a drain an n-type device.

FIG. 5 includes a schematic top view of a cascode amplifier having two p-type transistors and two n-type transistors, according to different aspects of the present disclosure.

FIG. 6 includes a cross-sectional view along line A-A′ in FIG. 5, according to different aspects of the present disclosure.

FIGS. 7-9 include cross-sectional views along line B-B′ in FIG. 5 according to different aspects of the present disclosure.

FIG. 10 schematically illustrates a top view of an inverter, according to different aspects of the present disclosure.

FIGS. 11-13 schematically illustrate top views of amplifiers of different configurations, according to different aspects of the present disclosure.

FIG. 14 includes a fragmentary cross-sectional view of a die that includes backside contacts couple to a common drain node where a drain of a p-type device is coupled to a drain an n-type device, according to different aspects of the present disclosure.

FIG. 15 illustrates a flowchart of a method 700 to form common backside contact, according to different aspects of the present disclosure.

FIG. 16 illustrates operations at various steps of method 700 in FIG. 15, according to the different aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. When describing aspects of a transistor, source/drain region(s) may refer to a source or a drain, individually or collectively, dependent upon the context.

The shrinkage in device dimensions presents stress on electrical routing. When only a frontside interconnect structure is present, the limited space may lead to smaller interconnect features, smaller spacing between neighboring metal features, and less-than-ideal heat dissipation. The tight spacing and the high contact resistance may lead to high resistance and capacitance, which may lead to low drive current and slow speed. In some existing technology, a backside interconnect structure is formed for power supply routing while the frontside interconnect structure remains home of signal routing. Metal routing connected to heat generating component also goes through the frontside interconnect structure and increases the thermal stress in the frontside interconnect structure.

The present disclosure provides a contact structure such that metal routing for heat generating components goes into a backside interconnect structure, instead of a frontside interconnect structure. In some embodiments, the backside interconnect structure engages a heat sink by way of a thermal interface material layer. The thermal interface material layer helps direct heat from the heat generating components into the heat sink. In some additional embodiments, the backside interconnect structure includes dummy pads that contact the thermal interface material layer. By electrically coupling the dummy pads to the heat generating components, heat from the heat generating components is readily dissipated through the dummy pads and the thermal interface material layer.

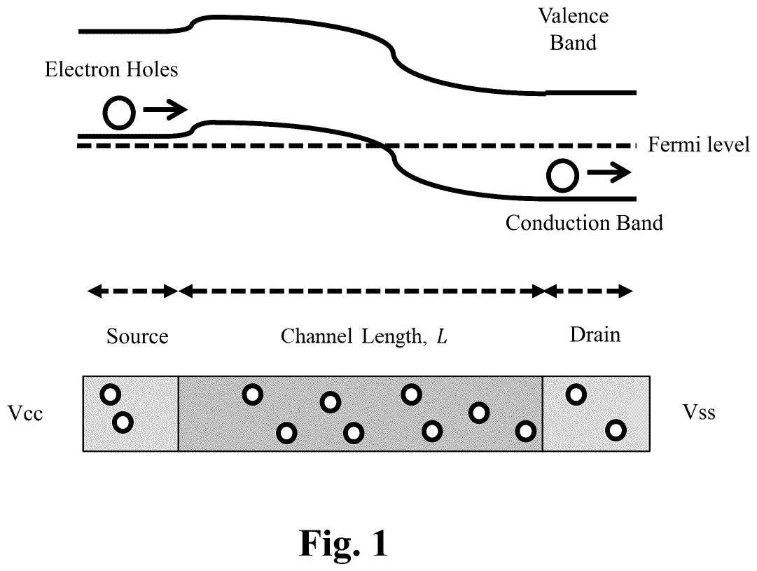

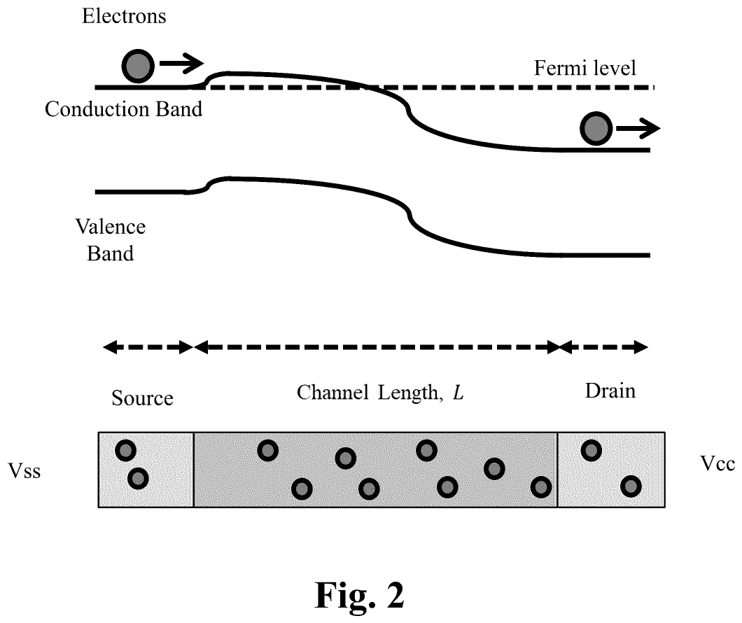

When activated, n-type transistors and p-type transistors have a “cool” source and a “hot” drain. Reference is first made to FIG. 1, which illustrates electrical current by movement of electron holes through a p-type device. In FIG. 1, the p-type device includes a source coupled to a positive supply voltage Vcc and a drain coupled to a negative supply voltage Vss. A channel with a channel length L is disposed between the source and the drain. When the channel of the p-type transistor is opened or activated, high energy electron holes flow from the source of the p-type device toward the drain of the p-type device. The leaving of the high-energy holes from the source cools the source of the p-type transistor. The collection of the high-energy holes heats up the drain of the p-type transistor. As a result, the p-type transistor may have a cool source and a hot drain. Reference is now made to FIG. 2, which illustrates electrical current by movement of electrons through an n-type device. In FIG. 2, the n-type device includes a source coupled to a negative supply voltage Vss and a drain coupled to a positive supply voltage Vcc. A channel with a channel length L is disposed between the source and the drain. When the channel of the n-type device is opened or activated, high energy electrons flow from the source of the n-type device toward the drain of the n-type device. The leaving of the high-energy electrons from the source cools the source of the n-type transistor. The collection of the high-energy electrons heats up the drain of the n-type transistor. As a result, the n-type transistor may have a cool source and a hot drain.

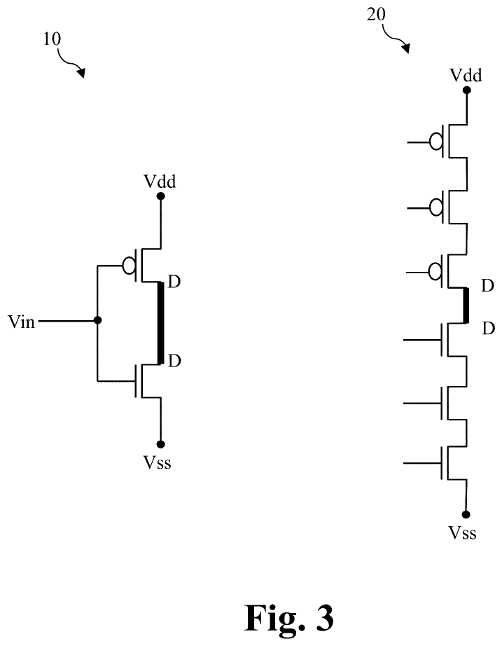

It is commonplace to see devices where a drain of a p-type device is coupled to a drain an n-type device. FIG. 3 illustrates two examples-an inverter 10 and a cascode amplifier 20. In logic circuits, an inverter is a logic gate that implements a logic negation. It outputs a bit opposite of the input bit. It may sometimes be referred to as a NOT gate. The inverter 10 in FIG. 3 includes one n-type transistor and one p-type transistor coupled together at their drains (D). The source of the n-type transistor in the inverter 10 is coupled to a negative power source Vss while the source of the p-type transistor in the inverter 10 is coupled to a positive power source Vcc. Gates of the p-type transistor and the n-type transistor may be coupled to receive an input voltage. A cascode amplifier is a multi-stage amplifier that is often used to improve input impedance, output impedance, or bandwidth. It can be used in many applications, such as in a current source. The term “cascode” means “cascade to cathode” and is used to refer to a configuration where an output of a device is connected to an input of another device. A cascode amplifier can be formed by connection of drains of a non-zero first number n-type transistors and a non-zero second number of p-type transistors, where at least one of the first number and the second number is greater than 1. A connection of two n-type transistors or two p-type transistors does not constitute a cascode amplifier because it is simply a drain-to-drain (output-to-output) connection. The cascode amplifier 20 includes a series of n-type transistors connected in series and a series of p-type transistor connected in series. A drain (D) terminal of the series of n-type transistors is connected to a drain (D) terminal of the series of p-type transistors. A source terminal of the series of n-type transistors is coupled to a negative power source Vss. A source terminal of the series of p-type transistors is coupled to a positive power source Vcc. Both the inverter 10 and the cascode amplifier 20 include an n-type drain and p-type drain coupled together.

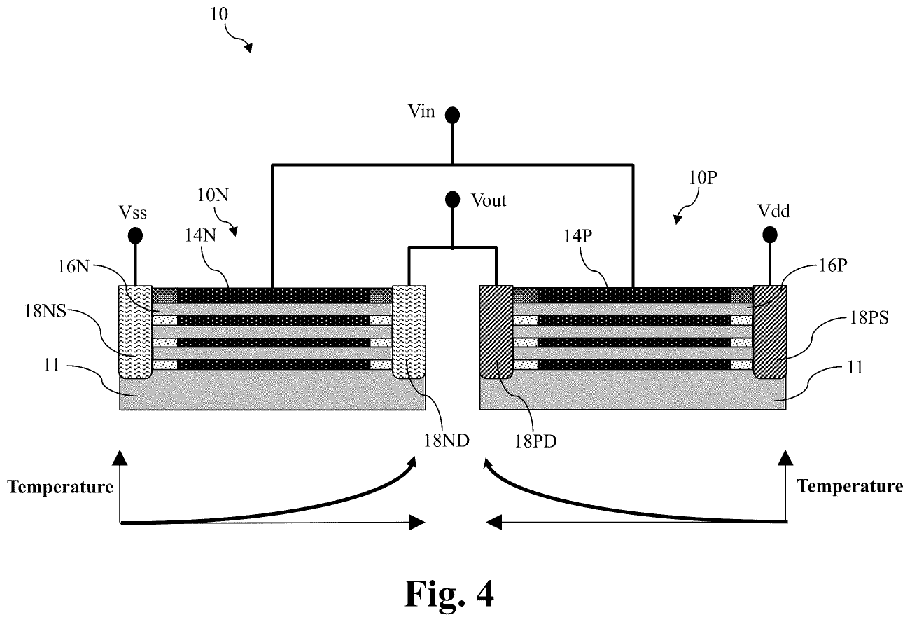

As described above, n-type transistors and p-type transistors include a “hot” drain and a “cool” source. When a cool source is coupled to a hot drain, the source cools the drain and drain heats the source, resulting in a controlled thermal condition. However, when two hot drains are coupled together, a local hot spot may be resulted. Reference is now made to FIG. 4, which illustrates an inverter 10 that includes an n-type transistor 10N and a p-type transistor 10P. In the depicted example, both the n-type transistor 10N and the p-type transistor 10P are gate-all-around (GAA) transistors. As illustrated in FIG. 4, the n-type transistor 10N includes a vertical stack of channel members 16N disposed over a substrate 11. The vertical stack of channel members 16N extends between an n-type source feature 18NS and an n-type drain feature 18ND. An n-type gate structure 14N wraps around each of the vertical stack of channel members 16N. The n-type source feature 18NS is coupled to a power source Vss. The p-type transistor 10P includes a vertical stack of channel members 16P disposed over the substrate 11. The vertical stack of channel members 16P extends between a p-type source feature 18PS and a p-type drain feature 18PD. A p-type gate structure 14P wraps around each of the vertical stack of channel members 16P. The p-type source feature 18PS is coupled to a positive power source Vdd. The n-type drain feature 18ND and the p-type drain feature 18PD are place adjacent to one another and coupled to an output node Vout. The n-type gate structure 14N and the p-type gate structure 14P are coupled together to an input node Vin. As schematically shown in FIG. 4, temperature increases from the n-type source feature 18NS to the n-type drain feature 18ND and increases from the p-type source feature 18PS to the p-type drain feature 18PD. Because none of the n-type drain feature 18ND and the p-type drain feature 18PD is cooled by a cool source feature, the temperature at the output node Vout is not balanced out and may shoot to an undesirable level. For purposes of the present disclosure, the connected n-type drain feature 16ND and p-type drain feature 16PD may also be referred to as hot drains or common drains.

In some embodiments, the substrate 11 may be a silicon (Si) substrate. In some other embodiments, the substrate 11 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), indium antimonide (InSb), gallium antimonide (GaSb), gallium indium antimonide (GaInSb), gallium indium phosphide (GaInP), and indium gallium arsenide (InGaAs). The substrate 11 may also include an insulating layer, such as a silicon oxide layer, to have a silicon-on-insulator (SOI) structure. The channel members 16N and 16P may be patterned from a stack of epitaxial layers formed over the substrate 11. In some embodiments, the channel members 16N and 16P may include silicon. The n-type source feature 18NS and n-type drain feature 18ND may include silicon (Si) and an n-type dopant, such as phosphorus (P) and arsenic (As). The p-type source feature 18PS and p-type drain feature 18PD may include silicon germanium (SiGe) and a p-type dopant, such as boron (B). The n-type gate structure 14N and the p-type gate structure 14P may include an interfacial layer, a gate dielectric layer over the interfacial layer, at least one work function layer, and a metal fill layer. The interfacial layer may include silicon oxide or hafnium silicate. The gate dielectric layer may include hafnium oxide, lanthanum oxide, zirconium oxide or aluminum oxide. The n-type gate structure 14N and the p-type gate structure 14P have different work function metal layers. The n-type work function layers in the n-type gate structure 14N may include titanium aluminum (TiAl) or titanium aluminum nitride (TiAlN). The p-type work function layers in the p-type gate structure 14P may include titanium nitride (TiN). The metal fill layer may include tungsten (W) or ruthenium (Ru).

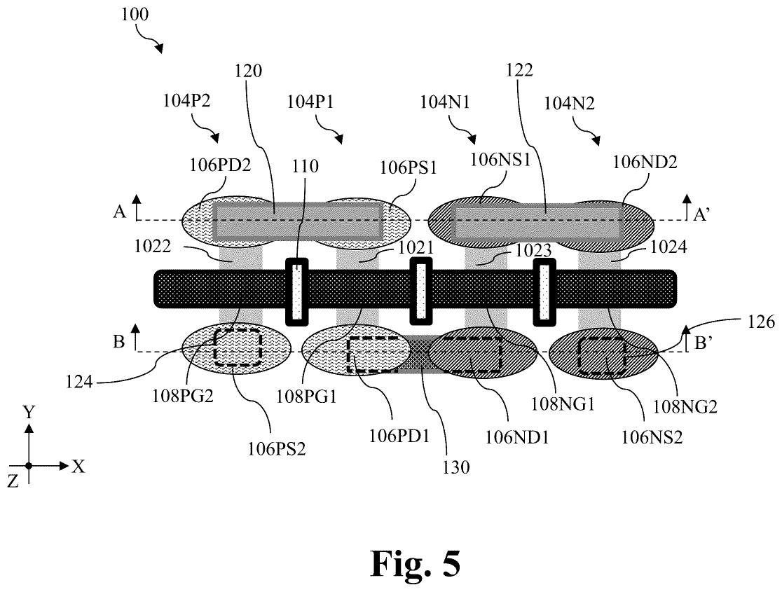

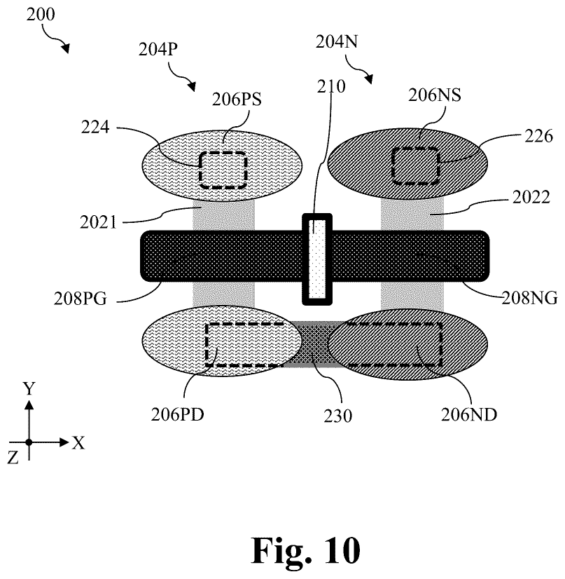

The present disclosure recognizes the temperature imbalance at the common drains and implements structures to direct heat from the common drains away from sensitive signal wires and toward a more readily assessable heat sink. To describe the various embodiments of the present disclosure, a fragmentary top view and fragmentary cross-sectional views of a cascode amplifier 100 are illustrated in FIGS. 5-9. It should be understood that the features of the present disclosures are readily applicable to common drains of inverters or cascode amplifiers of different configurations, some of which are illustrated in FIGS. 10-13.

Reference is first made to FIG. 5, which shows a schematic top view of a cascode amplifier 100. In the depicted embodiment, the cascode amplifier 100 include two p-type transistors and two n-type transistors connected in series. As illustrated in FIG. 5, the two p-type transistors are a first p-type transistor 104P1 and a second p-type transistor 104P2. The first p-type transistor 104P1 includes a first active region 1021 extending between a first p-type source feature 106PS1 and a first p-type drain feature 106PD1. A first p-type gate structure 108PG1 engages a channel region of the first active region 1021. The second p-type transistor 104P2 includes a second active region 1022 extending between a second p-type source feature 106PS2 and a second p-type drain feature 106PD2. A second p-type gate structure 108PG2 engages a channel region of the second active region 1022. The two n-type transistors are a first n-type transistor 104N1 and a second n-type transistor 104N2. The first n-type transistor 104N1 includes a third active region 1023 extending between a first n-type source feature 106NS1 and a first n-type drain feature 106ND1. A first n-type gate structure 108NG1 engages a channel region of the third active region 1023. The second n-type transistor 104N2 includes a fourth active region 1024 extending between a second n-type source feature 106NS2 and a second n-type drain feature 106ND2. A second n-type gate structure 108NG2 engages a channel region of the fourth active region 1024. The first p-type gate structure 108PG1, the second p-type gate structure 108PG2, the first n-type gate structure 108NG1, and the second n-type gate structure 108NG2 may be patterned from a continuous gate structure and are insulated from one another by gate cut features 110. In FIG. 5, the first p-type gate structure 108PG1, the second p-type gate structure 108PG2, the first n-type gate structure 108NG1, and the second n-type gate structure 108NG2 extend lengthwise along the X direction and the gate cut features 110 extend along the Y direction to separate them. The X direction is perpendicular to the Y direction. In some embodiments, the gate cut features 110 are not formed and may be omitted from FIG. 5.

The p-type transistors and the n-type transistors of the cascode amplifier 100 in FIG. 5 may be implemented using GAA transistors, fin-type field effect transistors (FinFETs) or planar devices. In the depicted embodiments, the p-type transistors and the n-type transistors of the cascode amplifier 100 are GAA transistors, similar to that schematically shown in FIG. 4. Referring to FIG. 5, each of the first active region 1021, the second active region 1022, the third active region 1023, and the fourth active region 1024 includes a vertical stack of channel members patterned from a stack of epitaxial layers formed a substrate (e.g., a silicon substrate). In some embodiments, the channel members in these four active regions may include silicon. The first n-type source feature 106NS1, the second n-type source feature 106NS2, the first n-type drain feature 106ND1, the second n-type drain feature 106ND2 may include silicon (Si) and an n-type dopant, such as phosphorus (P) and arsenic (As). The first p-type source feature 106PS1, the second p-type source feature 106PS2, the first p-type drain feature 106PD1, the second p-type drain feature 106PD2 may include silicon germanium (SiGe) and a p-type dopant, such as boron (B). The first n-type gate structure 108NG1, the second n-type gate structure 108NG2, the first p-type gate structure 108PG1, and the second p-type gate structure 108PG2 may include an interfacial layer, a gate dielectric layer over the interfacial layer, at least one work function layer, and a metal fill layer. The interfacial layer may include silicon oxide or hafnium silicate. The gate dielectric layer may include hafnium oxide, lanthanum oxide, zirconium oxide or aluminum oxide. The n-type gate structure 14N and the p-type gate structure 14P have different work function metal layers. The n-type work function layers in the first n-type gate structure 108NG1 and the second n-type gate structure 108NG2 may include titanium aluminum (TiAl) or titanium aluminum nitride (TiAlN). The p-type work function layers in the first p-type gate structure 108PG1 and the second p-type gate structure 108PG2 may include titanium nitride (TiN). The metal fill layer may include tungsten (W) or ruthenium (Ru). The gate cut features 110 may include silicon oxide, silicon nitride, silicon oxycarbonitride, silicon carbonitride, or a combination thereof.

Reference is still made to FIG. 5. A first frontside contact 120 extends over and engages both the first p-type source feature 106PS1 and the second p-type drain feature 106PD2. As will be described and illustrated in the cross-sectional view along line A-A′, the first frontside contact 120 extends downward to engage top surfaces of the first p-type source feature 106PS1 and the second p-type drain feature 106PD2, thereby electrically coupling them. The first p-type transistor 104P1 and the second p-type transistor 104P2 are connected in series by the first frontside contact 120. Similarly, a second frontside contact 122 extends over and engages both the first n-type source feature 106NS1 and the second n-type drain feature 106ND2. As will be described and illustrated in the cross-sectional view along line A-A′, the second frontside contact 122 extends downward to engage top surfaces of the first n-type source feature 106NS1 and the second n-type drain feature 106ND2, thereby electrically coupling them. The first n-type transistor 104N1 and the second n-type transistor 104N2 are connected in series by the second frontside contact 122. A first backside contact 124 is disposed below the second p-type source feature 106PS2 and extends upward to engage a bottom surface of the second p-type source feature 106PS2. The first backside contact 124 is configured to provide a supply voltage Vdd (i.e., high voltage power supply) to the cascode amplifier 100. A second backside contact 126 is disposed below the second n-type source feature 106NS2 and extends upward to engage a bottom surface of the second n-type source feature 106NS2. The second backside contact 126 is configured to provide a supply voltage Vss (i.e., low voltage power supply) to the cascode amplifier 100. A common backside contact 130 is disposed below the first p-type drain feature 106PD1 and the first n-type drain feature 106ND1 to engage at least bottom surfaces of the first p-type drain feature 106PD1 and the first n-type drain feature 106ND1. The common backside contact 130 electrically couple the two serially connected p-type transistors 104P1 and 104P2 and the two serially connect n-type transistors 104N1 and 104N2.

The first frontside contact 120 and the second frontside contact 122 provide connections to a frontside interconnect structure disposed over the first p-type transistor 104P1, the second p-type transistor 104P2, the first n-type transistor 104N1, and the second n-type transistor 104N2. The first backside contact 124, the second backside contact 126, and the common backside contact 130 provide connections to a backside interconnect structure disposed below the first p-type transistor 104P1, the second p-type transistor 104P2, the first n-type transistor 104N1, and the second n-type transistor 104N2. As shown in FIG. 5, in operation, the cooling of the first p-type source feature 106PS1 balances out the heating of the second p-type drain feature 106PD2. Similarly, the cooling of the first n-type source feature 106NS1 balances out the heating of the second n-type drain feature 106ND2. For that reason, the first frontside contact 120 and the second frontside contact 122 are thermally balanced and are less prone to undesirable local heating. This prevents undesirable heat to enter the crowded frontside connect structure that routes the signal. The second p-type source feature 106PS2 and the second n-type source feature 106NS2 are “cool” and so are the first backside contact 124 and the second backside contact 126. The same cannot be said for the common backside contact 130. The common backside contact 130 are coupled to both the first p-type drain feature 106PD1 and the first n-type drain feature 106ND1. The “hot” first p-type drain feature 106PD1 and the “hot” first n-type drain feature 106ND1 do not balance out. In fact, they work in synergy to heat up the common backside contact 130.

While the heating on the common drain node is inevitable, the common backside contact 130 direct the heat into the backside interconnect structure, instead of the frontside interconnect structure. Compared to the frontside interconnect structure, the backside interconnect structure is less crowded and less susceptible to thermal stress caused by the “hot” common drain node. Additionally, because the frontside interconnect structure for signal routing is disposed over the cascode amplifier 100, implementation of the common backside contact 130 keeps undesirable heat away from the frontside interconnect structure. As a result, the signal in the frontside interconnect structure is less likely to be impacted by the thermal stress caused by the common drain node. Further, as will be described further below, the backside interconnect structure may be coupled to an underlying device package that may serve as a heat sink. At least one dummy pad may be formed to electrically coupled to the common backside contact 130 to help direct heat into the seat sink. In some embodiments, the metal connections between the backside contacts of complementary metal oxide semiconductor (CMOS) devices (such as the cascode amplifier 100) to the power port in a device package serve as heat conduction path to a heat sink. Because the common backside contact 130 is formed near these metal connections, it can dissipate heat via these metal connections even if the common backside contact 130 is not directly coupled to these metal connections.

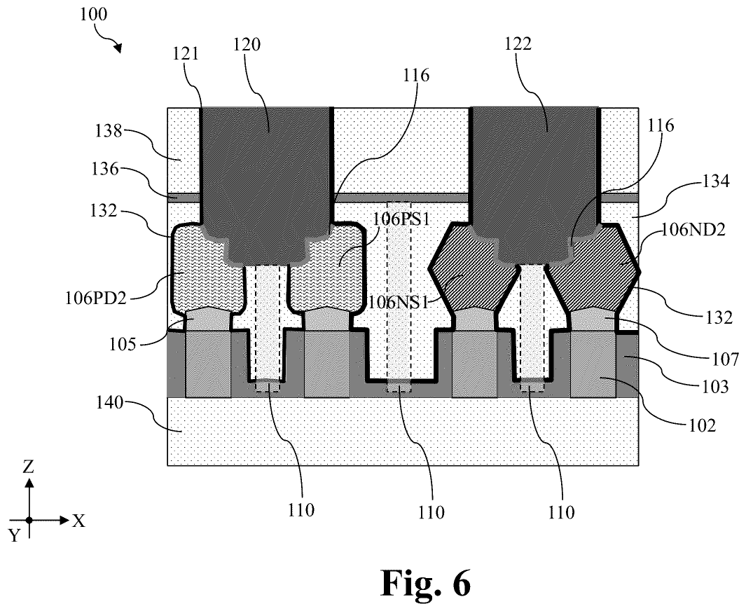

FIG. 6 illustrates a fragmentary cross-sectional view along line A-A′ in FIG. 5. Each of the first p-type source feature 106PS1, the second p-type drain feature 106PD2, the first n-type source feature 106NS1, and the second n-type drain feature 106ND2 is disposed over a base fin 102. The base fins 102 extend in parallel along the Y direction and are spaced apart from one another by an isolation structure 103. The isolation structure 103 may also be referred to as a shallow trench isolation (STI) structure 103. In some implementations, the isolation structure 103 may include silicon oxide. The base fins 102 are formed from a semiconductor substrate, such as a silicon substrate, which is now ground away. The base fins 102 and the isolation structure 103 are now disposed over a backside dielectric layer 140. In some embodiments where the substrate from which the base fins are formed is not completely removed by grinding or polishing, the backside dielectric layer 140 may be replaced by a residual thickness of the substrate. In some instances, the backside dielectric layer 140 may include silicon oxide. In some embodiments represented in FIG. 6, the first p-type source feature 106PS1 and the second p-type drain feature 106PD2 are not directly disposed on the base fins 102. Rather, a first undoped epitaxial feature 105 is sandwiched between the first p-type source feature 106PS1 and underlying base fin 102 and between the second p-type drain feature 106PD2 and the underlying base fin 102. The first undoped epitaxial feature 105 may include undoped silicon or undoped silicon germanium. The first n-type source feature 106NS1 and the second n-type drain feature 106ND2 are not directly disposed on the base fins 102. Rather, a second undoped epitaxial feature 107 is sandwiched between the first n-type source feature 106NS1 and underlying base fin 102 and between the second n-type drain feature 106ND2 and the underlying base fin 102. The second undoped epitaxial feature 107 may include undoped silicon or undoped silicon germanium. In some embodiments, the first undoped epitaxial feature 105 and the second undoped epitaxial feature 107 are of the same composition. In some alternative embodiments, the first undoped epitaxial feature 105 and the second undoped epitaxial feature 107 are of different compositions. In some embodiments, dielectric isolation layers, such as a silicon oxide layer or a silicon nitride layer, may be formed below the bottom of the source/drain features to reduce leakage into the substrate. In some implementations, the dielectric isolation layer may be formed below the first undoped epitaxial feature 105 or the second undoped epitaxial feature 107 to reduce leakage. Such dielectric isolation layer may be implemented in an n-type device, a p-type device, or both.

Referring still to FIG. 6, a contact etch stop layer (CESL) 132 may be disposed along surfaces of the first p-type source feature 106PS1, the second p-type drain feature 106PD2, the first n-type source feature 106NS1, the second n-type drain feature 106ND2, and the isolation structure 103. In some embodiments, the CESL 132 may include silicon nitride. A first interlayer dielectric (ILD) layer 134 is disposed over and in contact with the CESL 132 to substantially fill the vacant space. In some instances, the first ILD layer 134 may include silicon oxide. The first ILD 134 layer is planarized to have a planar top surface. An etch stop layer (ESL) 136 is disposed on the planar top surface of the first ILD 134 layer. In some instances, the ESL 136 may include silicon nitride, aluminum nitride, silicon oxycarbonitride, or aluminum oxide. A second ILD layer 138 is disposed over the ESL 136. The second ILD 138, like the first ILD 134, may also include silicon oxide. As illustrated in FIG. 6, the first frontside contact 120 extends through the second ILD layer 138, the ESL 136, the first ILD layer 134, and the CESL 132 to engage the first p-type source feature 106PS1 and the second p-type drain feature 106PD2 by way of a frontside silicide layer 116. The second frontside contact 122 extends through the second ILD layer 138, the ESL 136, the first ILD layer 134, and the CESL 132 to engage the first n-type source feature 106NS1 and the second n-type drain feature 106ND2 by way of the frontside silicide layer 116. The first frontside contact 120 and the second frontside contact 122 may include copper, cobalt, nickel, or tungsten. The frontside silicide layer 116 may include titanium silicide, cobalt silicide, nickel silicide, or tungsten silicide. In some embodiments, sidewalls of the first frontside contact 120 and the second frontside contact 122 are spaced apart from the second ILD layer 138, the ESL 136, and the first ILD layer 134 by a frontside liner 121. In some instances, the frontside liner 121 may include titanium nitride or silicon nitride. The first frontside contact 120 extends along the X direction over the first p-type source feature 106PS1 and the second p-type drain feature 106PD2. In some embodiments represented in FIG. 6, the first frontside contact 120 includes a middle portion that extends between the first p-type source feature 106PS1 and the second p-type drain feature 106PD2 along the X direction. This middle portion increases the interface area with the first p-type source feature 106PS1 and the second p-type drain feature 106PD2. In a similar manner, the second frontside contact 122 extends along the X direction over the first n-type source feature 106NS1 and the second n-type drain feature 106ND2. In some embodiments represented in FIG. 6, the second frontside contact 122 also includes a middle portion that extends between the first n-type source feature 106NS1 and the second n-type drain feature 106ND2 along the X direction. This middle portion increases the interface area with the first n-type source feature 106NS1 and the second n-type drain feature 106ND2.

In some embodiments represented in FIG. 6, gate cut features 110 (shown in dotted lines) may extend between the second p-type drain feature 106PD2 and the first p-type source feature 106PS1, between the first p-type source feature 106PS1 and the first n-type source feature 106NS1, or between the first n-type source feature 106NS1 and the second n-type drain feature 106ND2. The first front side contact 120 and the second front side contact 122 may interface the gate cut features 110.

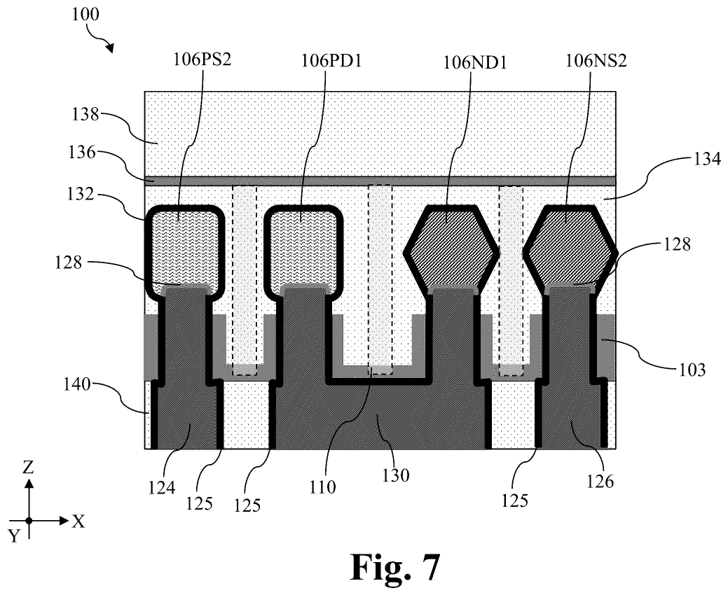

FIG. 7 illustrates a fragmentary cross-sectional view along line B-B′ in FIG. 5, according to a first example embodiment of the present disclosure. Each of the first p-type drain feature 106PD1, the second p-type source feature 106PS2, the first n-type drain feature 106ND1, and the second n-type source feature 106NS2 is disposed over a base fin 102. Referring to both FIGS. 6 and 7, the first p-type drain feature 106PD1 and the first p-type source feature 106PS1 are disposed over the same base fin 102; the second p-type drain feature 106PD2 and the second p-type source feature 106PS2 are disposed over the same base fin 102; the first n-type drain feature 106ND1 and the first n-type source feature 106NS1 are disposed over the same base fin 102; and the second n-type drain feature 106ND2 and the second n-type source feature 106NS2 are disposed over the same base fin 102. The base fins 102 extend in parallel along the Y direction and are spaced apart from one another by the isolation structure 103. The base fins 102 and the isolation structure 103 are disposed over the backside dielectric layer 140. The CESL 132 is disposed along surfaces of the first p-type drain feature 106PD1, the second p-type source feature 106PS2, the first n-type drain feature 106ND1, the second n-type source feature 106NS2, and the isolation structure 103. The first interlayer dielectric (ILD) layer 134 is disposed over and in contact with the CESL 132 to substantially fill the vacant space. The etch stop layer (ESL) 136 is disposed on the planar top surface of the first ILD 134 layer. The second ILD layer 138 is disposed over the ESL 136. As illustrated in FIG. 7, no frontside contacts extends through the second ILD layer 138, the ESL 136, the first ILD layer 134, and the CESL 132 to engage the first p-type drain feature 106PD1, the second p-type source feature 106PS2, the first n-type drain feature 106ND1, and the second n-type source feature 106NS2. The CESL 132 on surfaces the first p-type drain feature 106PD1, the second p-type source feature 106PS2, the first n-type drain feature 106ND1, and the second n-type source feature 106NS2 are not breached and are intact.

Reference is still made to FIG. 7. The first backside contact 124 extends through the backside dielectric layer 140, the base fin 102, and the first undoped epitaxial feature 105 to engage the second p-type source feature 106PS2 by way of a backside silicide layer 128. The second backside contact 126 extends through the backside dielectric layer 140, the base fin 102, and the second undoped epitaxial feature 107 to engage the second n-type source feature 106NS2 by way of the backside silicide layer 128. The common backside contact 130 includes a horizontal portion below the isolation structure 103 and two vertical portions to extend through the backside dielectric layer 140, the base fin 102, and the second undoped epitaxial feature 107 to engage the first n-type drain feature 106ND1 and the first p-type drain feature 106PD1 by way of the backside silicide layer 128. The first backside contact 124, the second backside contact 126, and the common backside contact 130 may include copper, cobalt, nickel, or tungsten. The backside silicide layer 128 may include titanium silicide, cobalt silicide, nickel silicide, or tungsten silicide. In some embodiments, sidewalls of the first backside contact 124, the second backside contact 126, and the common backside contact 130 are spaced apart from the backside dielectric layer 140 and the isolation structure 103 by a backside liner 125. In some instances, the backside liner 125 may include silicon nitride.

In some embodiments represented in FIG. 7, the gate cut features 110 (shown in dotted lines) may extend between the second p-type source feature 106PS2 and the first p-type drain feature 106PD1, between the first p-type drain feature 106PD1 and the first n-type drain feature 106ND1, or between the first n-type drain feature 106ND1 and the second n-type source feature 106NS2. In the depicted embodiment, the common backside contact 130 may be spaced apart from the gate cut feature 110 by a portion of the isolation feature 103. In some implementations where the gate cut features 110 extend further into the isolation feature, the common backside contact 130 may interface the common backside contact 130.

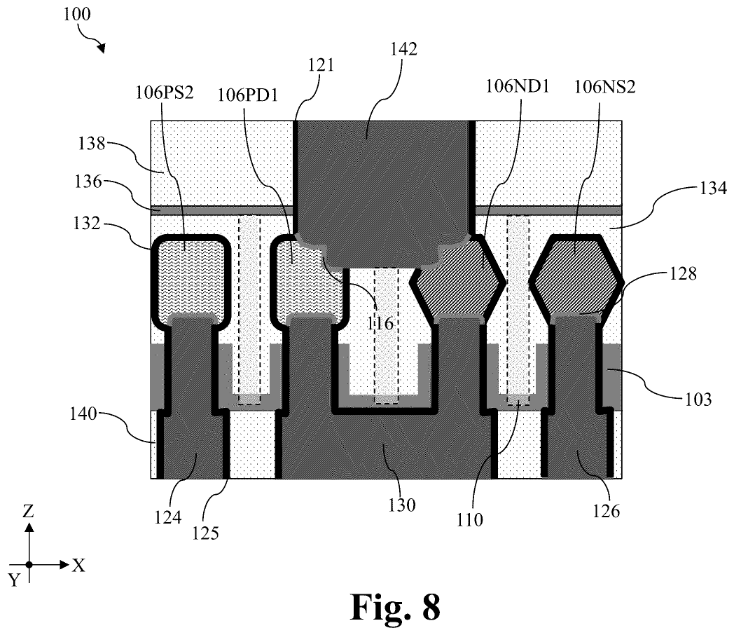

FIG. 8 illustrates a fragmentary cross-sectional view along line B-B′ in FIG. 5, according to a second example embodiment of the present disclosure. The second example embodiment in FIG. 8 is substantially similar to the first example embodiment in FIG. 7, except that a common frontside contact 142 extends through the second ILD layer 138, the ESL 136, the first ILD layer 134, and the CESL 132 to engage the first p-type drain feature 106PD1 and the first n-type drain feature 106ND1 by way of the frontside silicide layer 116. In some embodiments represented in FIG. 8, the common frontside contact 142 are spaced apart from the second ILD layer 138, the ESL 136, and the first ILD layer 134 by the frontside liner 121. In the second example embodiment in FIG. 8, both the common backside contact 130 and the common frontside contact 142 provide heat dissipation for the “hot” first p-type drain feature 106PD1 and first n-type drain feature 106ND1 during operation. In some embodiments, the common frontside contact 142 also includes a middle portion that extends further downward between sidewalls of the first p-type drain feature 106PD1 and the first n-type drain feature 106ND1 to increase heat conduction path.

In some embodiments represented in FIG. 8, the gate cut features 110 (shown in dotted lines) may extend between the second p-type source feature 106PS2 and the first p-type drain feature 106PD1, between the first p-type drain feature 106PD1 and the first n-type drain feature 106ND1, or between the first n-type drain feature 106ND1 and the second n-type source feature 106NS2. The common frontside contact 142 may interface one of the gate cut features 110.

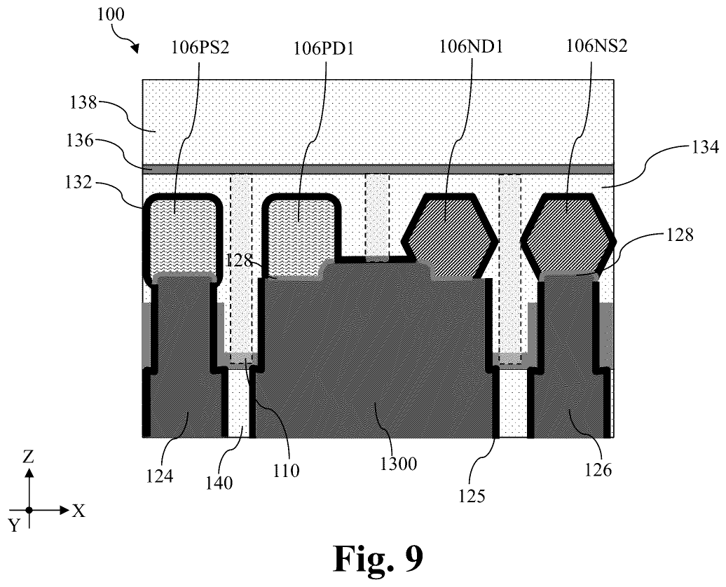

FIG. 9 illustrates a fragmentary cross-sectional view along line B-B′ in FIG. 5, according to a third example embodiment of the present disclosure. The third example embodiment in FIG. 9 is substantially similar to the first example embodiment in FIG. 7, except that the common backside contact 130 is replaced with an enlarged common backside contact 1300. Different from the common backside contact 130 in FIG. 7, formation of the opening for the enlarged common backside contact 1300 removes the isolation structure 103 between the base fins under the first p-type drain feature 106PD1 and the first n-type drain feature 106ND1. Instead of having a horizontal portion under the isolation structure 103 and two vertical portions extending to the first p-type drain feature 106PD1 and the first n-type drain feature 106ND1, the enlarged common backside contact 1300 includes a middle portion that extends between the first p-type drain feature 106PD1 and the first n-type drain feature 106ND1. Compared the common backside contact 130 in FIG. 7, the enlarged common backside contact 1300 has a greater engagement area (i.e., interface) with the first p-type drain feature 106PD1 and the first n-type drain feature 106ND1. This enlarged interface facilitate heat dissipation from the first p-type drain feature 106PD1 and the first n-type drain feature 106ND1.

In some embodiments represented in FIG. 9, the gate cut features 110 (shown in dotted lines) may extend between the second p-type source feature 106PS2 and the first p-type drain feature 106PD1, between the first p-type drain feature 106PD1 and the first n-type drain feature 106ND1, or between the first n-type drain feature 106ND1 and the second n-type source feature 106NS2. The enlarged common backside contact 1300 may interface one of the gate cut features 110.

FIGS. 10-13 illustrate amplifiers with different configurations. FIG. 10 illustrates an amplifier 200 that includes a p-type transistor 204P and an n-type transistor 204N connected in series. A p-type gate structure 208PG of the p-type transistor 204P engages a channel region of the first active region 2021 extending between a p-type source feature 206PS and a p-type drain feature 206PD. The n-type transistor 204N includes a second active region 2022 extending between an n-type source feature 206NS and an n-type drain feature 206ND. An n-type gate structure 208NG engages a channel region of the second active region 2022. The p-type gate structure 208PG and the n-type gate structure 208NG may be insulated from one another by a gate cut feature 210. In some embodiments, the gate cut feature 210 may extend between the n-type source feature 206NS and the p-type source feature 206PS as well as between n-type drain feature 206ND and the p-type drain feature 206PD. As illustrated in FIG. 10, a first backside contact 224 is disposed below the p-type source feature 206PS and extends upward to engage a bottom surface of the p-type source feature 206PS. The first backside contact 224 is configured to provide a supply voltage Vdd to the amplifier 200. A second backside contact 226 is disposed below the n-type source feature 206NS and extends upward to engage a bottom surface of the n-type source feature 206NS. The second backside contact 226 is configured to provide a supply voltage Vss to the amplifier 200. A common backside contact 230 is disposed below the p-type drain feature 206PD and the n-type drain feature 206ND to engage at least bottom surfaces of the p-type drain feature 206PD and the n-type drain feature 206ND. The common backside contact 230 electrically couple the p-type transistors 204P and the n-type transistor 204N.

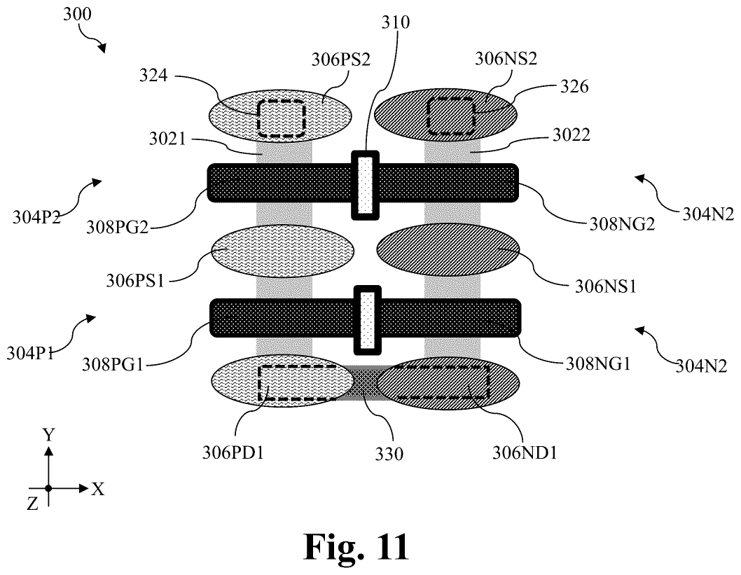

FIG. 11 illustrates a cascode amplifier 300 that includes two p-type transistors 304P1 and 304P2 and two n-type transistors 304N1 and 304N2 connected in series. The two p-type transistors 304P1 and 304P2 share a source/drain feature and a first active region 3021. The two n-type transistors 304N1 and 304N2 share a source/drain feature a second active region 3022. The sharing of the source/drain feature eliminates needs for frontside contacts that function as location interconnects. As shown in FIG. 11, a first p-type gate structure 308PG1 of the first p-type transistor 304P1 engages a channel region of the first active region 3021 extending between a first p-type drain feature 306PD1 and a first p-type source feature 306PS1. A second p-type gate structure 308PG2 of the second p-type transistor 304P2 engages another channel region of the first active region 3021 extending between the second p-type source feature 306PS2 and the first p-type source feature 306PS1, which also functions as the second p-type drain feature. A first n-type gate structure 308NG1 of the first n-type transistor 304N1 engages a channel region of the second active region 3022 extending between a first n-type drain feature 306ND1 and a first n-type source feature 306NS1. A second n-type gate structure 308NG2 of the second n-type transistor 304N2 engages another channel region of the second active region 3022 extending between the second n-type source feature 306NS2 and the first n-type source feature 306NS1, which also functions as the second n-type drain feature. The first p-type gate structure 308PG1 and the first n-type gate structure 308NG1 may be insulated from one another by a gate cut feature 310. In some embodiments, the gate cut feature 310 may extend continuously between source features and drain features of the n-type transistors and source features and drain features of the p-type devices without touching them. Similarly, the second p-type gate structure 308PG2 and the second n-type gate structure 308NG2 may be insulated from one another by another gate cut feature 310.

As illustrated in FIG. 11, a first backside contact 324 is disposed below the second p-type source feature 306PS2 and extends upward to engage a bottom surface of the second p-type source feature 306PS2. The first backside contact 324 is configured to provide a supply voltage Vdd to the cascode amplifier 300. A second backside contact 326 is disposed below the second n-type source feature 306NS2 and extends upward to engage a bottom surface of the second n-type source feature 306NS2. The second backside contact 326 is configured to provide a supply voltage Vss to the cascode amplifier 300. A common backside contact 330 is disposed below the first p-type drain feature 306PD1 and the first n-type drain feature 306ND1 to engage at least bottom surfaces of the first p-type drain feature 306PD1 and the first n-type drain feature 306ND1. The common backside contact 330 electrically couple the two serially connected p-type transistors 304P1 and 304P2 as well as the two n-type transistors 304N1 and 304N2.

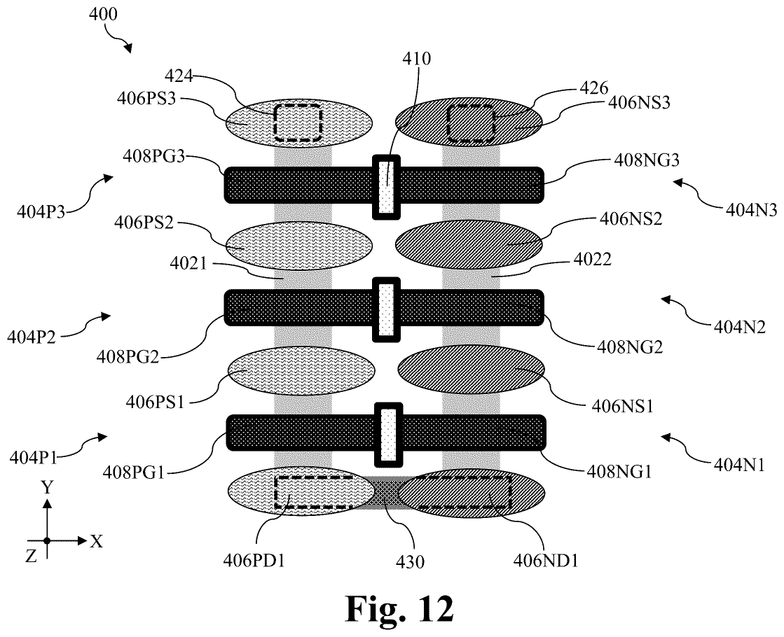

FIG. 12 illustrates a cascode amplifier 400 that includes three p-type transistors 404P1, 404P2 and 404P3 and three n-type transistors 404N1, 404N2 and 404N3 connected in series. The cascode amplifier 400 in FIG. 12 is similar to the cascode amplifier 300, except that the cascode amplifier 400 includes one more serially connected p-type transistor and one more serially connected n-type transistor. The additional serially connected transistors act like resistors for higher voltage applications. As shown in FIG. 12, the first p-type transistor 404P1 and the second p-type transistor 404P2 share a source/drain region and the second p-type transistor 404P2 and the third p-type transistor 404P3 share a source/drain region. The channel regions of the three p-type transistors 404P1, 404P2 and 404P3 are patterned from the same first active region 4021. The first n-type transistor 404N1 and the second n-type transistor 404N2 share a source/drain region and the second n-type transistor 404N2 and the third n-type transistor 404N3 share a source/drain region. The channel regions of the three n-type transistors 404N1, 404N2 and 404N3 are patterned from the same second active region 4022. As illustrated in FIG. 12, a first backside contact 424 is disposed below the third p-type source feature 406PS3 and extends upward to engage a bottom surface of the third p-type source feature 406PS3. The first backside contact 424 is configured to provide a supply voltage Vdd to the cascode amplifier 400. A second backside contact 426 is disposed below the third n-type source feature 406NS3 and extends upward to engage a bottom surface of the third n-type source feature 406NS3. The second backside contact 426 is configured to provide a supply voltage Vss to the cascode amplifier 400. A common backside contact 430 is disposed below the first p-type drain feature 406PD1 and the first n-type drain feature 406ND1 to engage at least bottom surfaces of the first p-type drain feature 406PD1 and the first n-type drain feature 406ND1. The common backside contact 430 electrically couple the three serially connected p-type transistors 404P1, 404P2, and 404P3 as well as the three serially connected n-type transistors 404N1, 404N2, and 404N3.

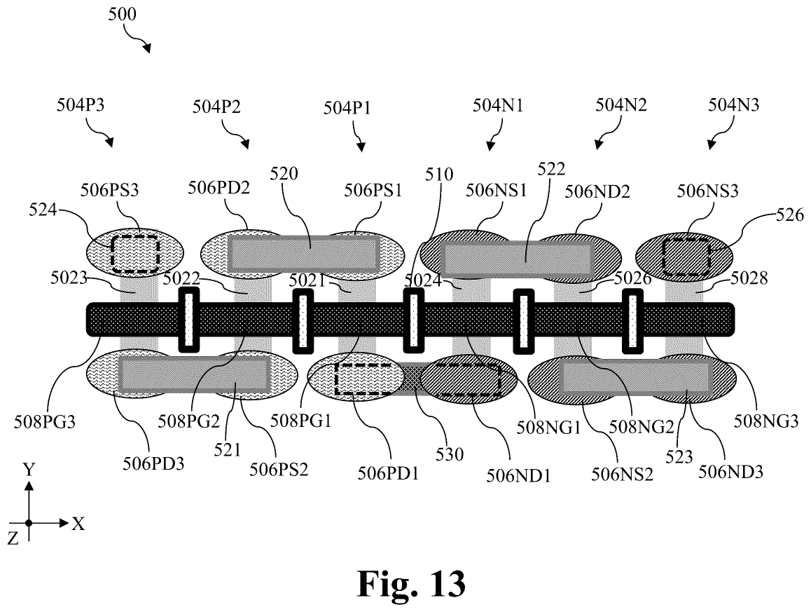

FIG. 13 illustrates a cascode amplifier 500 that includes three p-type transistors 504P1, 504P2 and 504P3 and three n-type transistors 504N1, 504N2 and 504N3 connected in series. The cascode amplifier 500 in FIG. 13 is similar to the cascode amplifier 100 in FIG. 5, except that the cascode amplifier 500 includes one more serially connected p-type transistor and one more serially connected n-type transistor. The cascode amplifier 500 includes three p-type transistors and three n-type transistors connected in series. As illustrated in FIG. 13, the three p-type transistors are a first p-type transistor 504P1, a second p-type transistor 504P2 and a third p-type transistor 504P3. The first p-type transistor 504P1 includes a first active region 5021 extending between a first p-type source feature 506PS1 and a first p-type drain feature 506PD1. A first p-type gate structure 508PG1 engages a channel region of the first active region 5021. The second p-type transistor 504P2 includes a second active region 5022 extending between a second p-type source feature 506PS2 and a second p-type drain feature 506PD2. A second p-type gate structure 508PG2 engages a channel region of the second active region 5022. The third p-type transistor 504P3 includes a third active region 5023 extending between a third p-type source feature 506PS3 and a third p-type drain feature 506PD3. A third p-type gate structure 508PG3 engages a channel region of the third active region 5023.

The three n-type transistors include a first n-type transistor 504N1, a second n-type transistor 504N2 and a third n-type transistor 504N3. The first n-type transistor 504N1 includes a fourth active region 5024 extending between a first n-type source feature 506NS1 and a first n-type drain feature 506ND1. A first n-type gate structure 508NG1 engages a channel region of the fourth active region 5024. The second n-type transistor 504N2 includes a fifth active region 5026 extending between a second n-type source feature 506NS2 and a second n-type drain feature 506ND2. A second n-type gate structure 508NG2 engages a channel region of the fifth active region 5026. The third n-type transistor 504N3 includes a sixth active region 5028 extending between a third n-type source feature 506NS3 and a third n-type drain feature 506ND3. A third n-type gate structure 508NG3 engages a channel region of the sixth active region 5028. The first p-type gate structure 508PG1, the second p-type gate structure 508PG2, the third p-type gate structure 508PG3, the first n-type gate structure 508NG1, and the second n-type gate structure 508NG2, and the third n-type gate structure 508NG3 may be patterned from a continuous gate structure and are insulated from one another by gate cut features 510.

Reference is still made to FIG. 13. A first frontside contact 520 extends over and engages both the first p-type source feature 506PS1 and the second p-type drain feature 506PD2. The first frontside contact 520 extends downward to engage top surfaces of the first p-type source feature 506PS1 and the second p-type drain feature 506PD2, thereby electrically coupling them. Similarly, a second frontside contact 522 extends over and engages both the first n-type source feature 506NS1 and the second n-type drain feature 506ND2. The third frontside contact 521 extends downward to engage top surfaces of the second p-type source feature 506PS2 and the third p-type drain feature 506PD3, thereby electrically coupling them. Similarly, a fourth frontside contact 523 extends over and engages both the second n-type source feature 506NS2 and the third n-type drain feature 506ND3. A first backside contact 524 is disposed below the third p-type source feature 506PS3 and extends upward to engage a bottom surface of the third p-type source feature 506PS3. The first backside contact 524 is configured to provide a supply voltage Vdd to the cascode amplifier 500. A second backside contact 526 is disposed below the third n-type source feature 506NS3 and extends upward to engage a bottom surface of the third n-type source feature 506NS3. The second backside contact 526 is configured to provide a supply voltage Vss to the cascode amplifier 500. A common backside contact 530 is disposed below the first p-type drain feature 506PD1 and the first n-type drain feature 506ND1 to engage at least bottom surfaces of the first p-type drain feature 506PD1 and the first n-type drain feature 506ND1. The common backside contact 530 electrically couple the three serially connected p-type transistors 504P1, 504P2 and 504P3 and the three serially connected n-type transistors 504N1, 504N2 and 504N3.

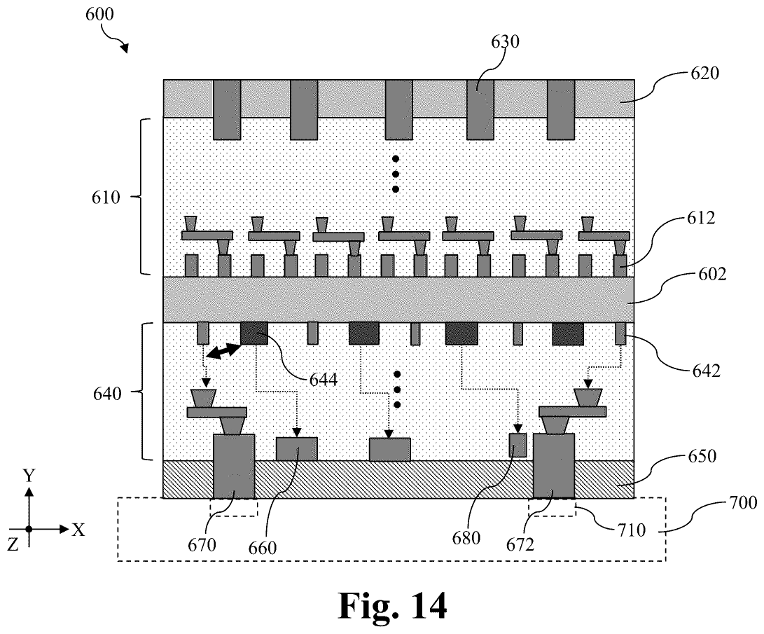

In addition to implementation of common backside contacts to direct heat of “hot” drains toward the backside interconnect structures, the present disclosure includes embodiments that further dissipate heat into a heat sink. Reference is now made to FIG. 14, which illustrates a fragmentary cross-sectional view of an integrated circuit (IC) die 600. As illustrated in FIG. 14, the IC die 600 includes a device layer 602 that includes transistors, such as GAA transistors described above or FinFETs. The IC die 600 includes a frontside interconnect structure 610 disposed over a front side of the device layer 602 and a backside interconnect structure 640 disposed below a back side of the device layer 602. Each of the frontside interconnect structure 610 and the backside interconnect structure 640 include via and contact features that provide vertical connections and conductive lines that provide horizontal connections. In some implementations, the frontside interconnect structure 610 may include eight (8) to twenty (20) levels of metal layers (or metallization layers) to route signal. The backside interconnect structure 640 may include less levels of metal layers for power rails. In some implements, the backside interconnect structure 640 may include three (3) to eight (8) levels of metal layers. For case of illustration, only a couple metallization layers are shown in each of the frontside interconnect structure 610 and the backside interconnect structure 640.

Each of the metal layers in the frontside interconnect structure 610 and the backside interconnect structure 640 may include an etch stop layer (ESL) and an intermetal dielectric (IMD) layer disposed on the ESL. The ESLs may share the same composition and may include silicon nitride or silicon oxynitride. The IMD layers may share the same composition and may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), low-k dielectric material, other suitable dielectric material, or combinations thereof. Example low-k dielectric materials include carbon doped silicon oxide, Xerogel, Aerogel, amorphous fluorinated carbon, benzocyclobutene (BCB), or polyimide. The metal lines and vias in the metal layers may include titanium (Ti), ruthenium (Ru), nickel (Ni), cobalt (Co), copper (Cu), molybdenum (Mo), tungsten (W), aluminum (Al), and/or other suitable materials.

The device layer 602 is fabricated on a substrate. The substrate may include silicon (Si). Alternatively, the substrate may include another elementary semiconductor, such as germanium (Ge); a compound semiconductor, such as silicon carbide (SiC), gallium arsenide (GaAs), gallium phosphide (GaP), indium phosphide (InP), indium antimonide (InSb), gallium antimonide (GaSb), indium arsenide (InAs), and/or indium antimonide; an alloy semiconductor, such as silicon germanium (SiGe), GaAsP, AlInAs, AlGaAs, (GInSb), GaInAs, GaInP, and/or GaInAsP; or combinations thereof. Alternatively, the substrate may be a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods. To provide mechanical strength when the substrate is ground away, a carrier substrate 620 is bonded over a top surface of the frontside interconnect structure 610. The carrier substrate 620 and the substrate for the device layer 602 may share a similar composition. In some embodiments represented in FIG. 14, the carrier substrate 620 is thinned such that through substrate vias 630 may extend through the carrier substrate 620 for signal routing. The formation of the through substrate vias 630 allows additional dies to be bonded over the IC die 600. As shown in FIG. 14, the IC die 600 includes frontside contacts 612, which are similar to the first frontside contact 120 and the second frontside contact 122 described above in conjunction with FIGS. 5 and 6.

Reference is still made to FIG. 7. The IC die 600 may be mounted on a package substrate 700, which may be a printed circuit board (PCB). In some embodiments, the IC dic 600 includes a thermal interface material (TIM) layer 650 to interface the package substrate 700. The TIM layer 650 may include a base material and thermally conductive fillers. In some implementations, the base material may include resin or epoxy and the thermally conductive filler may include metal oxide (e.g., beryllium oxide, aluminum oxide, or zinc oxide), metal nitride (e.g., aluminum nitride or hexagonal boron nitride), metal (i.e., copper, silver or aluminum), diamond, graphene, graphite, or a combination thereof. In some embodiments, the IC die 600 includes backside contacts 642, which are similar to the first backside contact 124 and the second backside contact 126 described above in conjunction with FIGS. 5 and 7-9. The backside contacts 642 are configured to provide a negative supply voltage or a positive supply voltage. In the depicted embodiments, the IC die 600 includes a first contact pad 670 to provide the positive supply voltage and a second contact pad 672 to provide the negative supply voltage. Through metal layers in the backside interconnect structure 640, the backside contacts 642 are electrically coupled to either the first contact pad 670 or the second contact pad 672. To draw power from the package substrate 700, both the first contact pad 670 and the second contact pad 672 extends completely through the TIM layer 650 to electrically couple to contact pads 710 on the package substrate 700. The TIM layer 650 may be regard to a heat sink or a portion of a heat sink.

Besides the backside contacts 642, the IC die 600 includes common backside contacts 644, which are similar to the common backside contact 130 described above in conjunction with FIGS. 5 and 7-9. The common backside contacts 644 are coupled to bottom surfaces of “hot” drain features of inverters or cascode amplifiers. In some embodiments, the common backside contacts 644 are not electrically coupled to any conductive features on the package substrate 700. While the common backside contacts 644 are not electrically coupled to any conductive features on the package substrate 700, they are thermally coupled to the TIM layer 650, the first contact pad 670, or the second contact pad 672. In some embodiments represented in FIG. 14, the common backside contacts 644 are electrically coupled to a first thermal interface feature 660 through metal lines and vias in the backside interconnect structure 640. The first thermal interface feature 660 is formed of titanium (Ti), ruthenium (Ru), nickel (Ni), cobalt (Co), copper (Cu), molybdenum (Mo), tungsten (W), aluminum (Al), or a combination thereof. As shown in FIG. 14, the first thermal interface feature 660 is in physical contact with the TIM layer 650 without being electrically coupled to any conductive features on the package substrate 700. The physical contact between the first thermal interface feature 660 and the TIM layer 650 allows thermal conduction directly into the TIM layer 650. In some alternative embodiments, the common backside contacts 644 are electrically coupled to a second thermal interface feature 680. The second thermal interface feature 680 may also include titanium (Ti), ruthenium (Ru), nickel (Ni), cobalt (Co), copper (Cu), molybdenum (Mo), tungsten (W), aluminum (Al), or a combination thereof. Different from the first thermal interface feature 660, the second thermal interface feature 680 is spaced apart from the package substrate 700 and an adjacent contact pad, such as the second contact pad 672 shown in FIG. 14. While the second thermal interface feature 680 is spaced apart from the package substrate 700 and an adjacent contact pad, a thickness of the IMD layer between the second thermal interface feature 680 and the TIM layer 650 or between the second thermal interface feature 680 of the second contact pad 672 is small enough such that the second thermal interface feature 680 is thermally coupled to the TIM layer 650 or the second contact pad 672. In some instances, the thickness of the IMD layer between the second thermal interface feature 680 and the TIM layer 650 or between the second thermal interface feature 680 of the second contact pad 672 is between about 50 nm and about 200 nm. Because the first thermal interface feature 660 and the second thermal interface feature 680 do not provide electrical connection to the package substrate 700, they may also be referred to as dummy pads or dummy contact pads. In some embodiments, the metal connections between the backside contacts 642 to the contact pads 672 serve as heat conduction path to cool down the devices in the device layer 602. When the common backside contacts 644 are formed near these metal connections, as indicated by the double-sided arrow in FIG. 14, they can dissipate heat via these metal connections even if the common backside contacts 644 is not directly coupled to these metal connections.

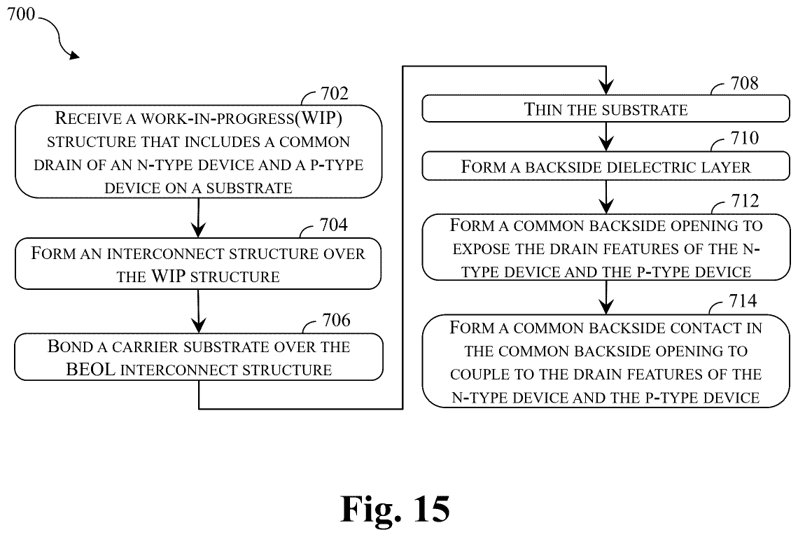

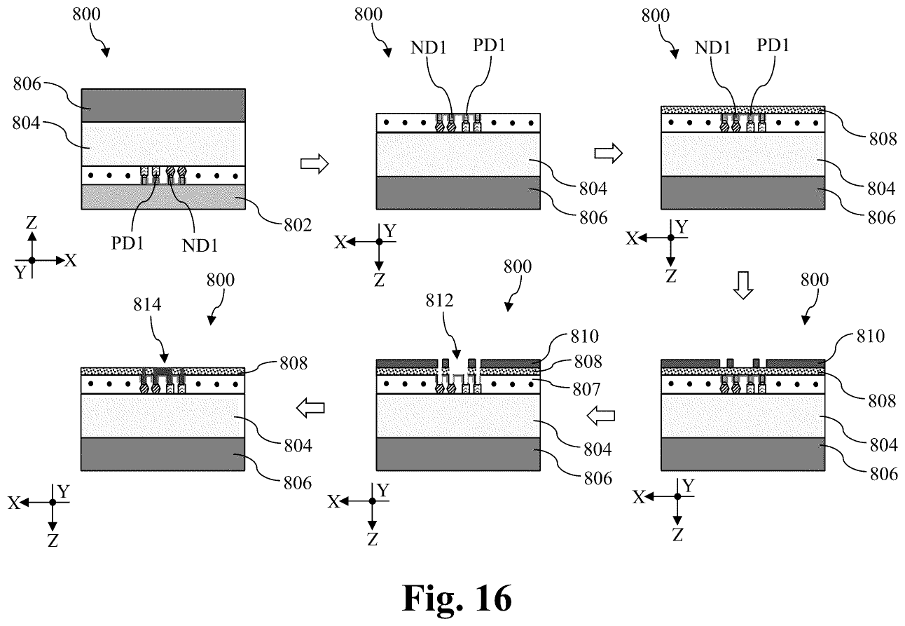

FIG. 15 illustrates a flowchart of a method 700 for forming a common backside contact according to the present disclosure. Method 700 is merely an example and is not intended to limit the present disclosure to what is explicitly illustrated in method 700. Additional steps may be provided before, during and after method 700, and some steps described can be replaced, eliminated, or moved around for additional embodiments of the methods. Not all steps are described herein in detail for reasons of simplicity. Method 700 is described below in conjunction with schematic fragmentary cross-sectional views of a work-in-progress (WIP) structure 800 in FIG. 16.

Referring to FIGS. 15 and 16, method 700 includes a block 702 where a WIP structure 800 is received. The WIP structure 800 includes an n-type device and a p-type device on a substrate 802 and an n-type drain NDI of the n-type device and a p-type drain PD1 of the p-type device are connected by a common drain. In some embodiments, the WIP structure 800 includes an inverter or a cascode amplifier similar those shown in FIG. 10 such that the n-type drain ND1 and the p-type drain PD1 are connected together to form a “hot drain” at a common drain node. The n-type device and the p-type device may be multi-gate transistors that are among many similar multi-gate transistors formed a front-end-of-line (FEOL) level over the substrate 802. Like the substrate 11 illustrated in FIG. 4, the substrate 802 may be a semiconductor substrate and may include silicon (Si). The n-type drain ND1 may include silicon (Si) and an n-type dopant and the p-type drain PD1 may include silicon germanium (SiGe) and a p-type dopant. In some embodiments, a gate cut feature, similar to the gate cut feature 110 shown in FIGS. 6 and 7, may extend between the n-type drain NDI and the p-type drain PD1

Referring to FIGS. 15 and 16, method 700 includes a block 704 where an interconnect structure 804 is formed over the WIP structure 800. The interconnect structure 804 may include between 8 and 20 metallization layers to functionally interconnect the multi-gate transistors at the FEOL level. Because the interconnect structure 804 is formed over a front side of the substrate 802, it may be referred to as a frontside interconnect structure.

Referring to FIGS. 15 and 16, method 700 includes a block 706 where a carrier substrate 806 over the interconnect structure 804. Because the substrate 802 is going to be substantially ground away in a subsequent step, the carrier substrate 806 is bonded to the interconnect structure 804 to provide mechanical strength. The carrier substrate 806 may include silicon, sapphire, quartz, or glass.

Referring to FIGS. 15 and 16, method 700 includes a block 708 where the substrate 202 is thinned. Once the carrier substrate 806 is attached to the WIP structure 800, the WIP structure 800 may be flipped upside down. A substantial portion of the substrate 802 is removed by grinding or polishing to expose base fins below the n-type drain NDI and the p-type drain PD1.

Referring to FIGS. 15 and 16, method 700 includes a block 710 where a backside dielectric layer 808 is formed over a backside of the WIP structure 800. After the substrate 802 is thinned, a backside dielectric layer 808 is formed over a backside surface of the WIP structure 800.

Referring to FIGS. 15 and 16, method 700 includes a block 712 where a common backside opening 812 is formed to expose backside surfaces of the n-type drain NDI and the p-type drain PD1. In some embodiments, a patterned mask layer 810 is formed over the backside dielectric layer 808. The patterned mask layer 810 includes a dielectric mask layer, a photoresist layer, or a combination thereof. To form the patterned mask layer 810, a mask layer is first blanketly formed over the backside dielectric layer 808. Lithography and etch steps are performed to patterned the mask layer to form the patterned mask layer 810. Using the patterned mask layer 810 as an etch mask, at least one dry etch process is performed to etch the backside dielectric layer 808 and the base fins to form a common backside opening 812. In one embodiment, the at least one dry etch process is more selective to the semiconductor material of the substrate 802 and etches an interlayer dielectric (ILD) layer between the base fins at a slower rate. In this embodiment, the common backside opening 212 includes two forks like the opening filled by the common backside contact 130 shown in FIGS. 7 and 8. In some alternative embodiments, the at least one dry etch process is not selective to the semiconductor material of the substrate and etches all materials at about the same rate. In these alternative embodiments, the common backside opening 212 may partially extend into the n-type drain NDI and the p-type drain PD1. As a result, the common backside opening 212 may be more like the opening filled by the enlarged common backside contact 1300 shown in FIG. 8. When a gate cut feature is present between the n-type drain NDI and the p-type drain PDI, formation of the common backside opening may include etching the gate cut feature.

Referring to FIGS. 15 and 16, method 700 includes a block 714 where a common backside contact 814 is formed in the common backside opening to couple to the n-type drain ND1 and the p-type drain PD1. The common backside contact 814 may include a silicide layer to interface the n-type drain ND1 and the p-type drain PDI and a metal fill. In some implementations, the silicide layer may include titanium silicide, cobalt silicide, nickel silicide, or tungsten silicide. The metal fill may include copper, cobalt, nickel, or tungsten. The common backside contact 814 may be spaced apart from surround dielectric structures, such as the ILD layer 807, by a dielectric liner. The dielectric liner may include silicon nitride.

In one example aspect, the present disclosure provides a semiconductor device. The semiconductor device includes a backside dielectric layer, a p-type transistor disposed over the backside dielectric layer and including a first p-type epitaxial feature, a second p-type epitaxial feature, a first active region extending between the first p-type epitaxial feature and the second p-type epitaxial feature along a first direction, and a first gate structure wrapping over the first active region, an n-type transistor disposed over the backside dielectric layer and including a first n-type epitaxial feature, a second n-type epitaxial feature, a second active region extending between the first n-type epitaxial feature and the second n-type epitaxial feature along the first direction, and a second gate structure wrapping over the second active region, a frontside dielectric layer over the first p-type epitaxial feature, the second p-type epitaxial feature, the first n-type epitaxial feature, and the second n-type epitaxial feature, and a backside contact extending through the backside dielectric layer to engage bottom surfaces of the first p-type epitaxial feature and the first n-type epitaxial feature.

In some embodiments, the semiconductor device further includes a gate cut feature sandwiched between the first gate structure and the second gate structure along the first direction. In some embodiments, the semiconductor device further includes an isolation feature disposed between the first active region and the second active region. In some implementations, the backside contact extends through the isolation feature. In some instances, the backside contact is spaced apart from the isolation feature by a dielectric liner and the dielectric liner includes silicon nitride. In some embodiments, the semiconductor device further includes a first frontside contact extending through the frontside dielectric layer to engage the second p-type epitaxial feature, and a second frontside contact extending through the frontside dielectric layer to engage the second n-type epitaxial feature. In some implementations, the semiconductor device further includes a third p-type epitaxial feature adjacent the second p-type epitaxial feature, and a third n-type epitaxial feature adjacent the second n-type epitaxial feature. The first frontside contact also engages the third p-type epitaxial feature. The second frontside contact also engages the third n-type epitaxial feature. In some embodiments, each of the first frontside contact and the second frontside contact extends lengthwise along a second direction perpendicular to the first direction. In some instances, the semiconductor device further includes a frontside interconnect structure over the frontside dielectric layer, a backside interconnect structure below the backside dielectric layer and including a dummy contact pad, and a thermal interface layer below the backside interconnect structure and engages the dummy contact pad. In some instances, the backside contact is electrically coupled to the dummy contact pad.

Another aspect of the present disclosure pertains to a semiconductor structure. The semiconductor structure includes a backside dielectric layer, a first p-type transistor disposed over the backside dielectric layer and including a first p-type epitaxial feature, a second p-type epitaxial feature, and a first active region extending between the first p-type epitaxial feature and the second p-type epitaxial feature along a first direction, a second p-type transistor disposed over the backside dielectric layer and including a third p-type epitaxial feature, a fourth p-type epitaxial feature, and a second active region extending between the third p-type epitaxial feature and the fourth p-type epitaxial feature along the first direction, a first n-type transistor disposed over the backside dielectric layer and including a first n-type epitaxial feature, a second n-type epitaxial feature, and a third active region extending between the first n-type epitaxial feature and the second n-type epitaxial feature along the first direction, a second n-type transistor disposed over the backside dielectric layer and including a third n-type epitaxial feature, a fourth n-type epitaxial feature, and a fourth active region extending between the third n-type epitaxial feature and the fourth n-type epitaxial feature along the first direction, and a common backside contact extending through the backside dielectric layer to engage bottom surfaces of the third p-type epitaxial feature and the first n-type epitaxial feature.

In some embodiments, the semiconductor structure further includes a first backside contact extending through the backside dielectric layer to engage a bottom surface of the first p-type epitaxial feature, and a second backside contact extending through the backside dielectric layer to engage a bottom surface of the third n-type epitaxial feature. In some embodiments, the semiconductor structure further includes a frontside dielectric layer disposed over the first p-type transistor, the second p-type transistor, the first n-type transistor, and the second n-type transistor, a first frontside contact extending through the frontside dielectric layer to engage the second p-type epitaxial feature and the fourth p-type epitaxial feature, and a second frontside contact extending through the frontside dielectric layer to engage the second n-type epitaxial feature and the fourth p-type epitaxial feature. In some embodiments, the first backside contact and the second backside contact are electrically isolated from the common backside contact. In some embodiments, a portion of the common backside contact extends directly between the third p-type epitaxial feature and the first n-type epitaxial feature.

Yet another aspect of the present disclosure pertains to a method. The method includes providing a structure that includes a substrate, a first base fin and a second base fin over the substrate, an n-type epitaxial feature disposed over the first base fin, a p-type epitaxial feature disposed over the second base fin, and forming an interconnect structure over the structure, bonding a carrier substrate over the interconnect structure, thinning the substrate to expose the first base fin and the second base fin from a back side of the substrate, depositing a backside dielectric layer over the back side of the substrate, forming a common contact opening through the backside dielectric layer, the first base fin and the second base fin to expose the n-type epitaxial feature and the p-type epitaxial feature, and forming a common backside contact in the common contact opening to couple to the n-type epitaxial feature and the p-type epitaxial feature.

In some embodiments, the structure further includes a gate cut feature extending between the n-type epitaxial feature and the p-type epitaxial feature and the forming of the common contact opening includes etching the gate cut feature. In some embodiments, the carrier substrate includes silicon, sapphire, quartz, or glass. In some embodiments, the n-type epitaxial feature is a part of an n-type transistor, the p-type epitaxial feature is a part of a p-type transistor, and the n-type transistor and the p-type transistor belong to an inverter or a cascode amplifier. In some embodiments, the common backside contact includes copper, cobalt, nickel, or tungsten, and the common backside contact interface the n-type epitaxial feature and the p-type epitaxial feature by way of silicide features.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device, comprising:
a backside dielectric layer;
a p-type transistor disposed over the backside dielectric layer and comprising:
a first p-type epitaxial feature,
a second p-type epitaxial feature,
a first active region extending between the first p-type epitaxial feature and the second p-type epitaxial feature along a first direction, and
a first gate structure wrapping over the first active region;
an n-type transistor disposed over the backside dielectric layer and comprising:
a first n-type epitaxial feature,
a second n-type epitaxial feature,
a second active region extending between the first n-type epitaxial feature and the second n-type epitaxial feature along the first direction, and
a second gate structure wrapping over the second active region;
a frontside dielectric layer over the first p-type epitaxial feature, the second p-type epitaxial feature, the first n-type epitaxial feature, and the second n-type epitaxial feature; and
a backside contact extending through the backside dielectric layer to engage bottom surfaces of the first p-type epitaxial feature and the first n-type epitaxial feature.

2. The semiconductor device of claim 1, further comprising:
a gate cut feature sandwiched between the first gate structure and the second gate structure along the first direction.

3. The semiconductor device of claim 1, further comprising:
an isolation feature disposed between the first active region and the second active region.

4. The semiconductor device of claim 3, wherein the backside contact extends through the isolation feature.

5. The semiconductor device of claim 4,
wherein the backside contact is spaced apart from the isolation feature by a dielectric liner,
wherein the dielectric liner comprises silicon nitride.

6. The semiconductor device of claim 1, further comprising:
a first frontside contact extending through the frontside dielectric layer to engage the second p-type epitaxial feature; and
a second frontside contact extending through the frontside dielectric layer to engage the second n-type epitaxial feature.

7. The semiconductor device of claim 6, further comprising:
a third p-type epitaxial feature adjacent the second p-type epitaxial feature; and
a third n-type epitaxial feature adjacent the second n-type epitaxial feature,
wherein the first frontside contact also engages the third p-type epitaxial feature,
wherein the second frontside contact also engages the third n-type epitaxial feature.

8. The semiconductor device of claim 6,
wherein each of the first frontside contact and the second frontside contact extends lengthwise along a second direction perpendicular to the first direction.

9. The semiconductor device of claim 1, further comprising:
a frontside interconnect structure over the frontside dielectric layer;
a backside interconnect structure below the backside dielectric layer and comprising a dummy contact pad; and
a thermal interface layer below the backside interconnect structure and engages the dummy contact pad.

10. The semiconductor device of claim 9, wherein the backside contact is electrically coupled to the dummy contact pad.

11. A semiconductor structure, comprising:
a backside dielectric layer;
a first p-type transistor disposed over the backside dielectric layer and comprising:
a first p-type epitaxial feature,
a second p-type epitaxial feature, and
a first active region extending between the first p-type epitaxial feature and the second p-type epitaxial feature along a first direction;
a second p-type transistor disposed over the backside dielectric layer and comprising:
a third p-type epitaxial feature,
a fourth p-type epitaxial feature, and
a second active region extending between the third p-type epitaxial feature and the fourth p-type epitaxial feature along the first direction;
a first n-type transistor disposed over the backside dielectric layer and comprising:
a first n-type epitaxial feature,
a second n-type epitaxial feature, and
a third active region extending between the first n-type epitaxial feature and the second n-type epitaxial feature along the first direction;
a second n-type transistor disposed over the backside dielectric layer and comprising:
a third n-type epitaxial feature,
a fourth n-type epitaxial feature, and
a fourth active region extending between the third n-type epitaxial feature and the fourth n-type epitaxial feature along the first direction; and
a common backside contact extending through the backside dielectric layer to engage bottom surfaces of the third p-type epitaxial feature and the first n-type epitaxial feature.

12. The semiconductor structure of claim 11, further comprising:
a first backside contact extending through the backside dielectric layer to engage a bottom surface of the first p-type epitaxial feature; and
a second backside contact extending through the backside dielectric layer to engage a bottom surface of the third n-type epitaxial feature.

13. The semiconductor structure of claim 12, further comprising:
a frontside dielectric layer disposed over the first p-type transistor, the second p-type transistor, the first n-type transistor, and the second n-type transistor;
a first frontside contact extending through the frontside dielectric layer to engage the second p-type epitaxial feature and the fourth p-type epitaxial feature; and
a second frontside contact extending through the frontside dielectric layer to engage the second n-type epitaxial feature and the fourth p-type epitaxial feature.

14. The semiconductor structure of claim 12, wherein the first backside contact and the second backside contact are electrically isolated from the common backside contact.

15. The semiconductor structure of claim 11, wherein a portion of the common backside contact extends directly between the third p-type epitaxial feature and the first n-type epitaxial feature.

16. A method, comprising:
providing a structure that includes:
a substrate,
a first base fin and a second base fin over the substrate,
an n-type epitaxial feature disposed over the first base fin,
a p-type epitaxial feature disposed over the second base fin, and
forming an interconnect structure over the structure;
bonding a carrier substrate over the interconnect structure;
thinning the substrate to expose the first base fin and the second base fin from a back side of the substrate;
depositing a backside dielectric layer over the back side of the substrate;
forming a common contact opening through the backside dielectric layer, the first base fin and the second base fin to expose the n-type epitaxial feature and the p-type epitaxial feature; and
forming a common backside contact in the common contact opening to couple to the n-type epitaxial feature and the p-type epitaxial feature.

17. The method of claim 16,
wherein the structure further includes a gate cut feature extending between the n-type epitaxial feature and the p-type epitaxial feature, and
wherein the forming of the common contact opening comprises etching the gate cut feature.

18. The method of claim 16, wherein the carrier substrate comprises silicon, sapphire, quartz, or glass.

19. The method of claim 16,
wherein the n-type epitaxial feature is a part of an n-type transistor,
wherein the p-type epitaxial feature is a part of a p-type transistor,
wherein the n-type transistor and the p-type transistor belong to an inverter or a cascode amplifier.

20. The method of claim 16,
wherein the common backside contact comprises copper, cobalt, nickel, or tungsten, and
wherein the common backside contact interface the n-type epitaxial feature and the p-type epitaxial feature by way of silicide features.
